(19) United States
(12) Patent Application Publication
(10) Pub. No.: US 2006/0124456 A1
(43) Pub. Date: Jun. 15, 2006

(54) Sputtering target, method for producing sputtering target, sputtering apparatus, and liquid-jet head

(75) Inventor: Masami Murai, Nagano-ken (JP)

Correspondence Address: SUGHRUE MION, PLLC, 2100 PENNSYLVANIA AVENUE, N.W., SUITE 800, WASHINGTON, DC, 20037, US

(73) Assignee: SEIKO EPSON CORPORATION

(21) Appl. No.: 11/288,211

(22) Filed: Nov. 29, 2005

(30) Foreign Application Priority Data
Dec. 2, 2004 (JP) 2004-350038

(51) Int. Cl. C23C 14/00

(52) U.S. Cl. 204/298.12

(57) ABSTRACT

A sputtering target, which is obtained by rolling a metallic material comprising platinum to form a metal plate having a predetermined thickness, and heating the metal plate for recrystallization, has crystallographic textures isotropic in any of the planar direction and the thickness direction, and has a maximum value of Vickers hardness of 60 or lower. A method for producing the sputtering target, a sputtering apparatus, and a liquid-jet head are also disclosed.

### BACKGROUND OF THE INVENTION

1. Field of the Invention

This invention relates to a sputtering target comprising platinum, which is used when forming a thin film on a substrate by the sputtering method; a method for producing the sputtering target; a sputtering apparatus; and a liquid-jet head.

2. Description of the Related Art

Liquid-jet heads, such as ink-jet recording heads, include those using a piezoelectric element to impart pressure for ejection of liquid droplets. In recent years, liquid-jet heads have been improved in performance and downsized. In accordance with these trends, such a piezoelectric element has been formed by laminating thin films. For example, a thin film comprising platinum or the like, which is formed by the sputtering method, has found wide use as an electrode of such a piezoelectric element (see, for example, Japanese. Patent Application Laid-Open No. 2001-88294.

As a sputtering target, which is used in forming such a thin film comprising platinum or the like by the sputtering method, the one formed by rolling a metallic material (ingot), for example, is used generally (see, for example, Japanese Patent Application Laid-Open No. 1994-330298.

However, the formation of the thin film on the substrate using the sputtering target poses the problem of difficulty in rendering the thickness of the film uniform. Concretely, the sputtering target formed by rolling has crystallographic textures which are anisotropic. Thus, depending on whether the substrate is placed horizontally or vertically with respect to the crystal orientation of the sputtering target, for example, the sputtering rate changes. Moreover, the sputtering target is consumed as a result of thin film formation, and the amount of its consumption is not constant in the planar direction of the target. If the crystallographic textures are anisotropic, therefore, the sputtering rate is prone to changes over time. Consequently, even if the same sputtering target is used under the same sputtering conditions, the thickness of the film formed on the substrate is nonuniform, resulting in variations in sheet resistance.

Furthermore, the displacement characteristics of the piezoelectric element for use in the liquid-jet head or the like are mainly determined, for example, by the crystallinity of a piezoelectric layer composed of a piezoelectric material, such as crystal grain size or crystal orientation. The crystallinity of the piezoelectric layer varies with the film thickness or film quality of a lower electrode. To form a piezoelectric element having satisfactory displacement characteristics, therefore, it is necessary to form the lower electrode in a uniform film thickness and of a uniform film quality.

### SUMMARY OF THE INVENTION

The present invention has been accomplished in the light of the above-mentioned circumstances. It is an object of the present invention to provide a sputtering target, which can form the thin film on the substrate in a uniform thickness and in a satisfactory manner, a method for producing the sputtering target, a sputtering apparatus, and a liquid-jet head.

A first aspect of the present invention for attaining the above object is a sputtering target obtained by rolling a metallic material comprising platinum to form a metal plate having a predetermined thickness, and heating the metal plate for recrystallization, the sputtering target having crystallographic textures isotropic in any of a planar direction and a thickness direction thereof, and a maximum value of Vickers hardness of 60 or lower.

In the first aspect, since the sputtering target described above is actually used, changes in the sputtering rate during formation of a thin film can be kept small. Thus, a thin film uniform in thickness is always obtained and, as a result, variations in its sheet resistance are also prevented.

A second aspect of the present invention is the sputtering target according to the first aspect, characterized in that a minimum value of the Vickers hardness is 50 or higher.

In the second aspect, variations in the hardness of the sputtering target are so small that changes in the sputtering rate are rendered smaller.

A third aspect of the present invention is the sputtering target according to the first or second aspect, characterized in that textures formed by rolling do not remain.

In the third aspect, changes in the sputtering rate are suppressed more reliably.

A fourth aspect of the present invention is a sputtering apparatus comprising a cathode having the sputtering target of any one of the first to third aspects fixed thereto, and a holding means for holding a substrate disposed in opposed relationship with the sputtering target.

In the fourth aspect, changes in the sputtering rate during formation of a thin film can be kept small. Thus, a thin film uniform in thickness is always obtained and, as a result, variations in the sheet resistance of the thin film can also be prevented.

A fifth aspect of the present invention is the sputtering apparatus according to the fourth aspect, characterized in that the sputtering target is disposed at a position eccentric with respect to a center of the substrate held by the holding means.

In the fifth aspect, the thickness of the thin film formed on the substrate can be rendered further uniform.

A sixth aspect of the present invention is a liquid-jet head comprising a piezoelectric element having a lower electrode comprising a platinum film formed by the sputtering target of any one of the first to third aspects.

In this sixth aspect, the piezoelectric layer with satisfactory crystallinity is formed on the lower electrode film. Thus, a liquid-jet head improved in the characteristics of liquid ejection by driving of the piezoelectric element can be achieved.

A seventh aspect of the present invention is a liquid-jet head comprising a piezoelectric element having a lower electrode comprising a platinum film formed by the sputtering apparatus of the fourth or fifth aspect.

In this seventh aspect, the piezoelectric layer with satisfactory crystallinity is formed on the lower electrode film. Thus, a liquid-jet head improved in the characteristics of liquid ejection by driving of the piezoelectric element can be achieved.

A eighth aspect of the present invention is a method for producing a sputtering target, comprising: a rolling step of rolling a metallic material comprising platinum to form a metal plate having a predetermined thickness; and a reheating step of heating the metal plate for recrystallization so that crystallographic textures constituting the metal plate are isotropic in any of a planar direction and a thickness direction of the metal plate, and a maximum value of Vickers hardness of the metal plate is 60 or lower.

In the eighth aspect, a sputtering target having a satisfactory crystal structure and few changes in the sputtering rate can be formed.

An ninth aspect of the present invention is the method for producing a sputtering target according to the seventh aspect, characterized in that a heating temperature of the metal plate in the reheating step is 800° C. or higher.

In the ninth aspect, the metal plate can be reliably recrystallized. Thus, a sputtering target having a satisfactory crystal structure can be more reliably formed.

### BRIEF DESCRIPTION OF THE DRAWINGS

For a more complete understanding of the present invention and the advantages thereof, reference is now made to the following descriptions in conjunction with the accompanying drawings.

FIG. 1 is a schematic view of a sputtering apparatus according to an embodiment of the present invention.

FIG. 2 is a view schematically showing the crystal state of a sputtering target according to the present invention.

FIG. 3 is a view schematically showing the crystal state of a conventional sputtering target.

FIG. 4 is a view illustrating the position of observation of the sputtering target.

FIG. 5 is a perspective view showing the outline of a recording head according to an-embodiment of the present invention.

FIGS. 6A and 6B are, respectively, a plan view and a sectional view of the recording head according to the embodiment of the present invention.

FIGS. 7A to 7D are sectional views showing a manufacturing process for the recording head according to the embodiment of the present invention.

FIGS. 8A to 8D are sectional views showing the manufacturing process for the recording head according to the embodiment of the present invention.

FIGS. 9A to 9D are sectional views showing the manufacturing process for the recording head according to the embodiment of the present invention.

FIGS. 10A to 10C are sectional views showing the manufacturing process for the recording head according to the embodiment of the present invention.

### DESCRIPTION OF THE PREFERRED EMBODIMENTS

The present invention will now be described in detail based on the embodiments offered below.

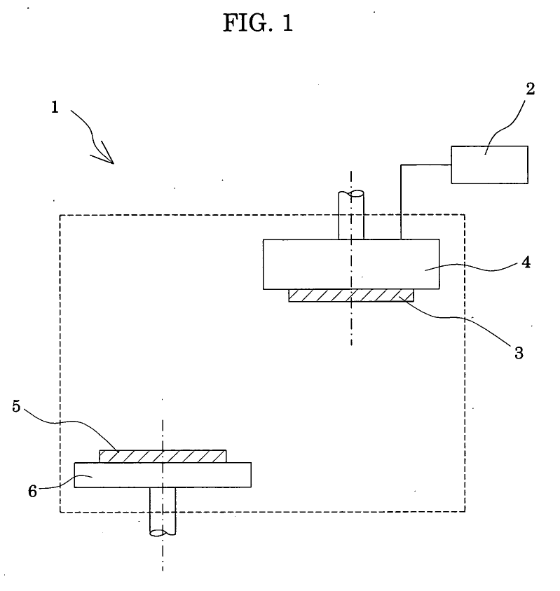

FIG. 1 is a schematic view of a sputtering apparatus according to an embodiment of the present invention. A sputtering apparatus 1 according to the present embodiment is a magnetron sputtering apparatus. As shown in FIG. 1, the sputtering apparatus 1 comprises, for example, a magnetron cathode 4 connected to a DC power source 2 and having a sputtering target 3 fixed thereto, and a holding member 6 provided in opposed relationship with the sputtering target 3 and holding a predetermined substrate 5. The magnetron cathode 4 and the holding member 6 are disposed in a vacuum chamber, although this is not shown. In the present embodiment, moreover, the sputtering target 3 is provided at a position eccentric with respect to the center of the substrate 5. In this state, the substrate is preferably rotated. By so doing, the thickness of a thin film formed on the substrate can be rendered more uniform. To arrange a plurality of the magnetron cathodes, it is permissible to tilt the magnetron cathodes in accordance with the size of the vacuum chamber. Of course, the sputtering target 3 may be disposed such that its center aligns with the center of the substrate 5.

The spacing between the sputtering target 3 and the substrate 5 is desirably relatively large; for example, it is 100 mm or more. Given such a spacing, a thin film can be formed in a relatively uniform thickness on the substrate 5. The holding member 6 is connected to a drive means such as a motor and, during formation of a thin film, is rotated at a rotational speed of about 30 rpm.

The sputtering target 3 according to the present invention is formed by rolling a metallic material comprising platinum to form a metal plate, and recrystallizing the metal plate. Concretely, a metallic material (ingot) comprising platinum is rolled to form a metal plate having a predetermined thickness, for example, a thickness of the order of 3 to 10 mm. Then, the metal plate is recrystallized in a nitrogen (N₂) atmosphere at a predetermined temperature to form the sputtering target 3.

The temperature for recrystallization of the metal plate is preferably a temperature which is a half or more of the melting point of the metal plate (platinum). That is, the temperature is preferably about 800° C. or higher, more preferably 900° C. or higher. Too high a temperature of recrystallization, however, is not preferred, because the metal plate is influenced by the atmosphere. In the present embodiment, for example, the metal plate is recrystallized for about 1 hour in a nitrogen (N₂) atmosphere at about 900° C.

In the resulting sputtering target 3 according to the present invention, textures remaining in the metal plate formed by rolling are recrystallized, with the result that the crystallographic textures are isotropic in any of the planar direction and the thickness direction. Besides, the sputtering target 3 is composed globally of crystals having a relatively uniform grain size. Isotropy of the crystallographic textures means that the metallographic structures do not comprise rectangular crystal grains, which have minor axes and major axes, in the planar direction and the plate thickness direction. In the case of platinum, the crystal structure is a face-centered cubic system. Thus, the crystal grains produced by rolling constitute a structure in which the major axes are in the <111>-direction of platinum.

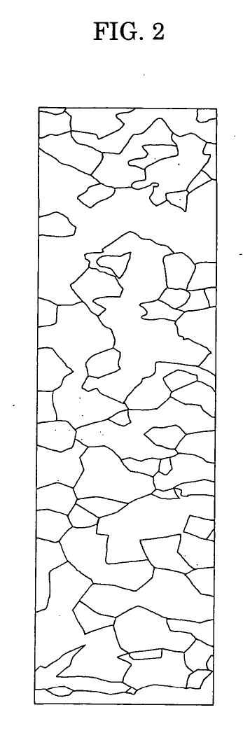

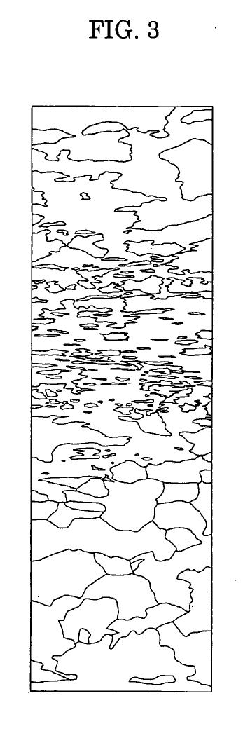

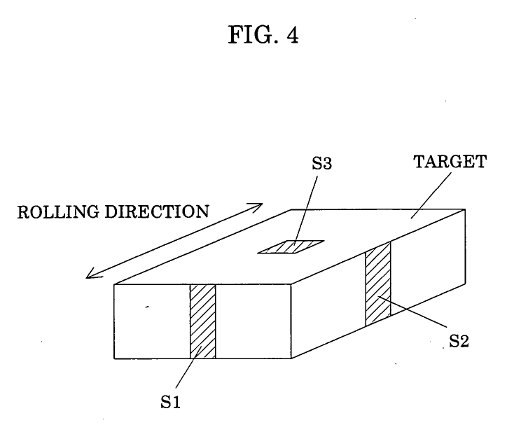

FIG. 2 schematically shows the crystal state of the sputtering target 3 according to the present invention which has been formed by rolling the metallic material comprising platinum, and then recrystallizing the rolled material. FIG. 3 schematically shows the crystal state of a conventional sputtering target which has been formed by rolling a metallic material comprising platinum. FIGS. 2 and 3 are views showing the crystal state in a sectional region S1 in a direction perpendicular to the direction of rolling as shown in FIG. 4.

Observation of the crystal state in the sectional region S1 of the sputtering target 3 according to the present invention yielded the following findings: As shown in FIG. 2, the textures generated by rolling do not remain at all, and the structure is constituted entirely of crystals having a relatively uniform grain size. The same results of observation were obtained in a sectional region S2 and a planar region S3 sampled parallel to the rolling direction (see FIG. 4), although these observation results are not illustrated. As demonstrated by the observation results, in the sputtering target 3 according to the present invention, the crystallographic textures are isotropic in any of the planar direction and the thickness direction.

On the other hand, the crystal state was observed in the sectional region S1 of the conventional sputtering target formed by rolling alone. As shown in FIG. 3, a texture remained at least in a middle portion in the thickness direction. This texture is generated in portions with a high degree of processing by rolling, and is not limited to the central portion of the target. A similar observation was made in other regions, and such a texture was found to remain in the sectional region S2. As these observation results show, the crystallographic textures of the conventional sputtering target were anisotropic.

Furthermore, the sputtering target according to the present invention not only has the isotropic crystallographic textures, but is also relatively low in the maximum value of Vickers hardness. In the present embodiment, for example, the Vickers hardness was 60 or lower on the surface of the sputtering target, or in any position of the section of the sputtering target. For example, the Vickers hardness was measured at 10 locations in the sectional region S1 shown in FIG. 2. The values of the Vickers hardness at these locations were all within the range of 50 to 60. That is, the sputtering target 3 according to the present embodiment is relatively low and very uniform as a whole in the Vickers hardness. Similarly, the Vickers hardness was measured in the sectional region S1 of the conventional sputtering target shown in FIG. 3. The maximum value was a relatively high value of 72, and the values of the Vickers hardness at various sites of measurement were in a relatively wide range of 50 to 75, showing variations in the hardness. Moreover, as the number of the textures increases, the Vickers hardness tends to increase.

By forming a thin film using the above-described sputtering target 3 according to the present invention, a dense thin film in a uniform thickness can be always formed on the substrate 5. That is, the sputtering rate is nearly constant, regardless of the direction of disposition of the substrate 5 with respect to the sputtering target 3. Furthermore, since the crystallographic textures are isotropic, changes in the sputtering rate over time, which are associated with the consumption of the sputtering target 3, can be kept small. Particularly in the present embodiment, variations in the hardness of the sputtering target 3 are kept to a minimum, so that changes in the sputtering rate are also rendered very small. Thus, a dense thin film comprising platinum can always be formed in a uniform thickness on the substrate. As a result, its sheet resistance is also uniform.

If a lower electrode film, which constitutes a piezoelectric element, is formed using the above sputtering target, the effect of improving the displacement characteristics of the piezoelectric element is obtained. An ink-jet recording head will be described hereinbelow as an example of a device using a piezoelectric element.

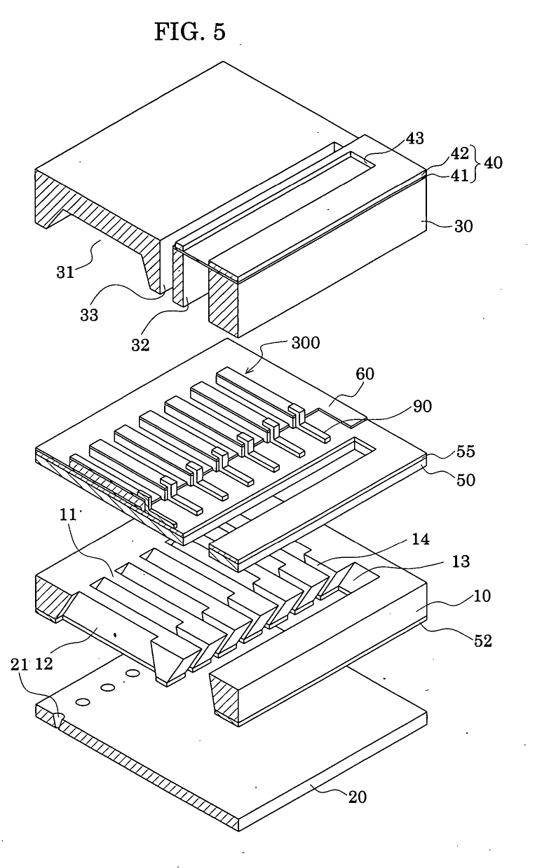

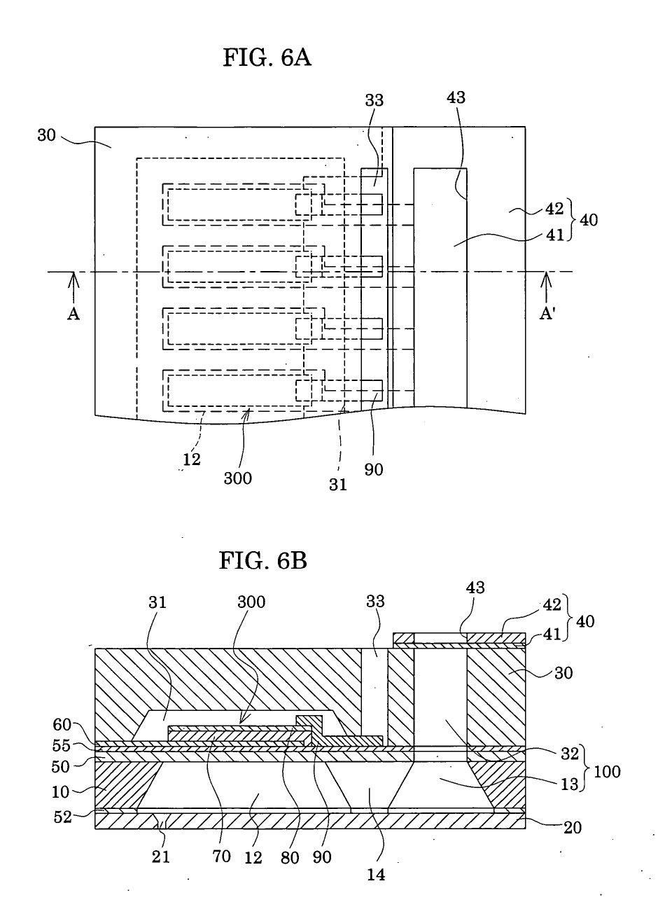

FIG. 5 is an exploded perspective view showing an ink-jet recording head according to an embodiment of the present invention. FIG. 6A and FIG. 6B are a plan view and a sectional view, respectively, of the ink-jet recording head in FIG. 5. As illustrated in these drawings, a passage-forming substrate 10, in the present embodiment, consists of a single crystal silicon substrate having a plane (110) of the plane orientation. An elastic film 50, 0.5 to 2 μm thick and comprising silicon dioxide, has been formed beforehand on one surface of the passage-forming substrate 10 by thermal oxidation.

In the passage-forming substrate 10, a plurality of pressure generating chambers 12 are arranged parallel in the width direction thereof. In a region longitudinally outward of the pressure generating chambers 12 of the passage-forming substrate 10, a communicating portion 13 is formed. The communicating portion 13 and each pressure generating chamber 12 are brought into communication via an ink supply path 14 provided for each pressure generating chamber 12. The communicating portion 13 communicates with a reservoir portion 32 of a protective plate 30 (to be described later) to constitute a reservoir 100 serving as a common ink chamber for the respective pressure generating chambers 12. The ink supply path 14 is formed in a smaller width than that of each pressure generating chamber 12, and maintains the passage resistance of ink, which flows from the communicating portion 13 into the pressure generating chamber 12, at a constant value.

Onto the opening surface of the passage-forming substrate 10, a nozzle plate 20 having nozzle orifices 21 bored therein is secured via an adhesive agent or a heat sealing film. The nozzle orifices 21 communicate with portions close to the ends of the pressure generating chambers 12 on the side opposite to the ink supply paths 14. The nozzle plate 20 comprises a glass ceramic having a thickness of, for example, 0.01 to 1 mm, and a linear expansion coefficient of, for example, 2.5 to 4.5 [×10⁻⁶/° C.] at 300° C. or below a single crystal silicon substrate, or stainless steel.

On the surface of the passage-forming substrate 10 opposite to the nozzle plate 20, the elastic film 50 having-a thickness, for example, of about 1.0 μm is formed, as described above. An insulation film 55 having a thickness, for example, of about 0.4 μm is formed on the elastic film 50. On the insulation film 55, a lower electrode film 60 with a thickness, for example, of about 0.2 μm, a piezoelectric layer 70 with a thickness, for example, of about 1.0 μm, and an upper electrode film 80 with a thickness, for example, of about 0.05 μm are formed in a laminated state by a process (to be described later) to constitute a piezoelectric element 300. The piezoelectric element 300 refers to a portion including the lower electrode film 60, the piezoelectric layer 70, and the upper electrode film 80. Generally, one of the electrodes of the piezoelectric element 300 is used as a common electrode, and the other electrode and the piezoelectric layer 70 are constructed for each pressure generating chamber 12 by patterning. A portion, which is composed of any one of the electrodes and the piezoelectric layer 70 that have been patterned, and which undergoes piezoelectric distortion upon application of voltage to both electrodes, is called a piezoelectric active portion. In the present embodiment, the lower electrode film 60 is used as the common electrode for the piezoelectric elements 300, while the upper electrode film 80 is used as an individual electrode of each piezoelectric element 300. However, there is no harm in reversing their usages for the convenience of a drive circuit or wiring. In either case, it follows that the piezoelectric active portion is formed for each pressure generating chamber. Herein, the piezoelectric element 300 and a vibration plate, where displacement occurs by a drive of the piezoelectric element 300, are referred to collectively as a piezoelectric actuator.

A lead electrode 90 is connected to the upper electrode film 80 of each piezoelectric element 300, and a voltage is applied selectively to each piezoelectric element 300 via the lead electrode 90.

The protective plate 30, which has a piezoelectric element holding portion 31 in a region opposed to the piezoelectric elements 300, is bonded onto the passage-forming substrate 10 on which the piezoelectric elements 300 are located. Since the piezoelectric elements 300 are formed within the piezoelectric element holding portion 31, they are protected in a state in which they are minimally influenced by an external environment. Further, the reservoir portion 32 is provided in a region of the protective plate 30 corresponding to the communicating portion 13 of the passage-forming substrate 10. The reservoir portion 32, in the present embodiment, is provided so as to penetrate the protective plate 30 in its thickness direction and extend along the direction of parallel arrangement of the pressure generating chambers 12. As described earlier, the reservoir portion 32 is brought into communication with the communicating portion 13 of the passage-forming substrate 10 to constitute the reservoir 100 which serves as the common ink chamber for the respective pressure generating chambers 12. In a region of the protective plate 30 defined between the piezoelectric element holding portion 31 and the reservoir portion 32, a through-hole 33 is provided which penetrates the protective plate 30 in its thickness direction. In the through-hole 33, a part of the lower electrode film 60 and a front end portion of the lead electrode 90 are exposed. An end of connecting wire extending from a drive IC is connected to the lower electrode film 60 and the lead electrode 90, although this is not shown.

The material for the protective plate 30 is, for example, glass, a ceramic material, a metal, or a resin. Preferably, the protective plate 30 is formed of a material having nearly the same thermal expansion coefficient as that of the passage-forming substrate 10. In the present embodiment, the protective plate 30 is formed from a single crystal silicon substrate which is the same material as that for the passage-forming substrate 10.

Further, a compliance plate 40 composed of a sealing film 41 and a fixing plate 42 is bonded onto a region of the protective plate 30 corresponding to the reservoir portion 32. The sealing film 41 comprises a low-rigidity flexible material (for example, a polyphenylene sulfide (PPS) film having a thickness of 6 μm), and one surface of the reservoir portion 32 is sealed with the sealing film 41. The fixing plate 42 is formed of a hard material such as a metal (for example, a stainless steel (SUS) having a thickness of 30 μm). A region of the fixing plate 42 opposed to the reservoir 100 defines an opening portion 43 in which the fixing plate 42 has been completely removed in its thickness direction. Thus, one surface of the reservoir 100 is sealed only with the sealing film 41 having flexibility.

With the ink-jet recording head of the present embodiment as described above, ink is taken in from an external ink supply means (not shown) to render the interior of the ink-jet recording head, ranging from the reservoir 100 to the nozzle orifices 21, full of the ink. Then, in accordance with recording signals from the drive IC (not shown), a voltage is applied between the lower electrode film 60 and the upper electrode film 80 corresponding to the pressure generating chamber 12 to warp and deform the piezoelectric element 300 and the vibration plate. As a result, the pressure within the pressure generating chamber 12 is raised to eject ink through the nozzle orifice 21.

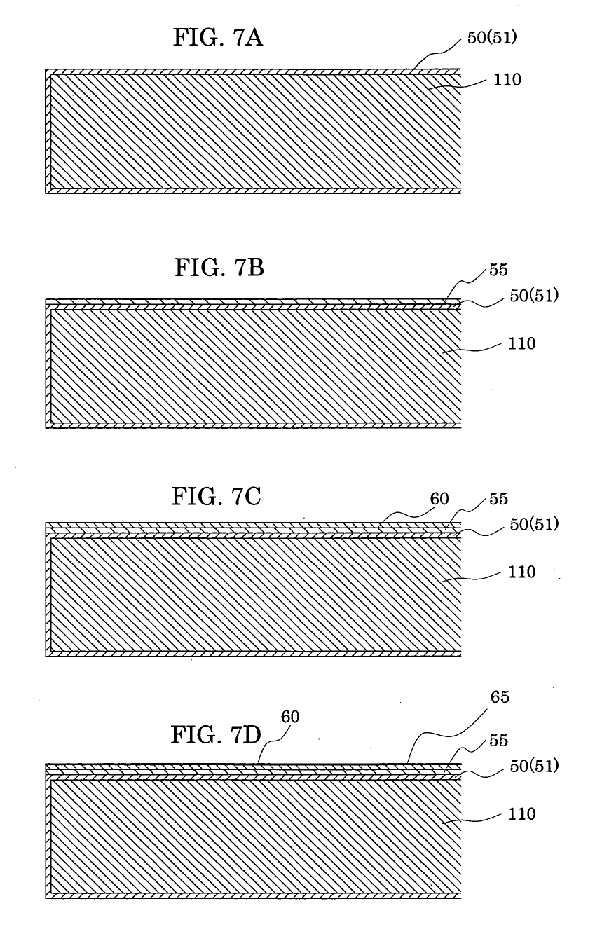

The method for producing the above-described ink-jet recording head, especially, the method for producing the piezoelectric element, will be described with reference to FIGS. 7A to 7D through FIGS. 10A to 10C. These drawings are views showing the section in the longitudinal direction of the pressure generating chamber.

First, as shown in FIG. 7A, a passage-forming substrate wafer 110, which is a silicon wafer, is thermally oxidized in a diffusion furnace at about 1,100° C. to form a silicon dioxide film 51 constituting the elastic film 50 on the surface of the wafer 110. In the present embodiment, a silicon wafer having a relatively large thickness of about 625 μm and having high rigidity is used as the passage-forming substrate wafer 110.

Then, as shown in FIG. 7B, the insulation film 55 comprising zirconium oxide is formed on the elastic film 50 (silicon dioxide film 51). Speciffically, a zirconium (Zr) layer is formed on the elastic film 50 (silicon dioxide film 51), for example, by the sputtering method. Then, the zirconium layer is thermally oxidized, for example, in a diffusion furnace at 500 to 1,200° C. to form the insulation film 55 comprising zirconium oxide (ZrO₂).

Then, as shown in FIG. 7C, platinum and iridium, for example, are deposited on the insulation film 55 by the sputtering method to form the lower electrode film 60 which is a thin film. In the present embodiment, the lower electrode film 60 is formed by use of the aforementioned sputtering apparatus furnished with the sputtering target (see FIG. 1). By so doing, the lower electrode film 60 can be formed in a uniform film thickness.

Then, as shown in FIG. 7D, titanium (Ti) is coated on the lower electrode film 60 and the insulation film 55, for example, by the sputtering method to form a seed titanium layer 65 having a predetermined thickness. The seed titanium layer 65 is preferably stacked in such a manner as to be continuous with the lower electrode film 60. Also, the seed titanium layer 65 serves as a nucleus for the crystals of the piezoelectric layer 70 to be formed in a step to be described later. The crystal grain size and crystal orientation of the piezoelectric layer 70 vary with the thickness of the seed titanium layer 65. The grain size of the piezoelectric layer 70 is desirably relatively small, for example, 200 nm or less. To obtain the piezoelectric layer 70 with such a grain size, it is necessary to form the seed titanium layer 65 in a thickness of about 2 nm or more.

Then, the piezoelectric layer 70 comprising, for example, lead zirconate titanate (PZT) is formed on the resulting seed titanium layer 65. In the present embodiment, the piezoelectric layer 70 is formed by the so-called sol-gel process which comprises dissolving or dispersing metal organic materials in a catalyst to form a sol, coating and drying the sol to form a gel, and firing the gel at a high temperature to obtain the piezoelectric layer 70 comprising the metal oxide.

The method for forming the piezoelectric layer 70 is not limited to the sol-gel process and, for example, MOD (metal-organic decomposition) may be used. The material for the piezoelectric layer 70 is, for example, a ferroelectric piezoelectric material such as lead zirconate titanate (PZT), or a relaxor ferroelectric having a metal, such as niobium, nickel, magnesium, bismuth or yttrium, added to such a ferroelectric piezoelectric material. The composition of the piezoelectric layer 70 may be chosen, as appropriate, in consideration of the characteristics, uses, etc. of the piezoelectric element 300. Examples of this are PbTiO₃ (PT), PbZrO₃ (PZ), Pb(ZrₓTi₁₋ₓ)O₃ (PZT), Pb(Mg_{1/3}Nb_{2/3})O₃—PbTiO₃ (PMN—PT), Pb(Zn_{1/3}Nb_{2/3})O₃—PbTiO₃ (PZN—PT), Pb(Ni_{1/3}Nb_{2/3})O₃—PbTiO₃ (PNN—PT), Pb(In_{1/2}Nb_{1/2})O₃—PbTiO₃ (PIN—PT), Pb(Sc_{1/2}Ta_{1/2})O₃—PbTiO₃ (PST—PT), Pb(Sc_{1/2}Nb_{1/2})O₃—PbTiO₃ (PSN—PT), BiScO₃—PbTiO₃ (BS—PT), and BiYbO₃—PbTiO₃ (BY—PT).

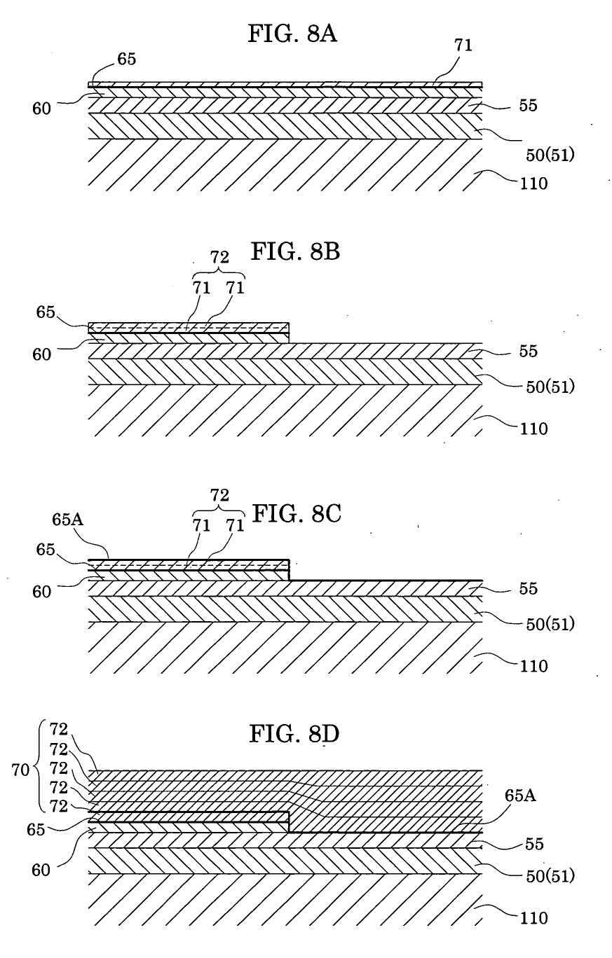

The specific procedure for forming the piezoelectric layer 70 will be described. First, as shown in FIG. 8A, a piezoelectric precursor film 71, which is a PZT precursor film, is deposited on the seed titanium layer 65. That is, a sol (solution) containing a metal organic compound is coated on the passage-forming substrate wafer 110. Then, the piezoelectric precursor film 71 is heated to a predetermined temperature and dried for a predetermined period of time to evaporate the solvent of the sol, thereby drying the piezoelectric precursor film 71. Further, the piezoelectric precursor film 71 is degreased for a predetermined time at a constant temperature in an air atmosphere. Degreasing refers to oxidizing the organic components of the sol film to release them, for example, as NO₂, CO₂, and H₂O.

This process, comprising coating, drying and degreasing, is repeated a predetermined number of times, for example, two times in the present embodiment. By this operation, the piezoelectric precursor film 71 is formed to a predetermined thickness, and the so treated piezoelectric precursor film 71 is heat-treated in a diffusion furnace for crystallization, whereby a piezoelectric film 72 is formed, as shown in FIG. 8B. That is, the piezoelectric precursor film 71 is fired, whereby crystals grow, with the seed titanium layer 65 as the nucleus, to form the piezoelectric film 72. In the present embodiment, for example, the piezoelectric precursor film 71 is fired with heating for 30 minutes at about 700° C. to form the piezoelectric film 72. The crystals of the so formed piezoelectric film 72 show preferred orientation into the (100)-plane. After the piezoelectric film 72 is thus formed on the lower electrode film 60, the piezoelectric film 72 and the lower electrode film 60 are patterned into predetermined shapes. In the present embodiment, after formation of the piezoelectric film 72 composed of two of the piezoelectric precursor films 71, the piezoelectric film 72 and the lower electrode film 60 are patterned into predetermined shapes. However, it is acceptable to form the piezoelectric film consisting of the single piezoelectric precursor film, and pattern the piezoelectric film and the lower electrode film.

Then, as shown in FIG. 8C, a seed titanium layer 65A is formed again on the patterned piezoelectric film 72 and the lower electrode film 60. Then, the above-described process, comprising coating, drying, degreasing and firing, is repeated a plurality of times to form a piezoelectric layer 70 of a predetermined thickness consisting of a plurality of (five in the present embodiment) the piezoelectric films 72, as shown in FIG. 8D. If the film thickness per coating of the sol is of the order of 0.1 μm, for example, the total film thickness of the piezoelectric layer 70 is about 1 μm.

The characteristics of the piezoelectric layer 70 formed in this manner vary according to the film thickness of the lower electrode film 60 and so forth, as stated earlier. The film thickness of the lower electrode film 60 can be rendered uniform by forming the lower electrode film 60 with the use of the sputtering target according to the present invention, as mentioned previously. Thus, the film thickness of the seed titanium layer formed on the lower electrode film 60 is controlled, thereby making it possible to form the piezoelectric layer 70 having satisfactory crystallinity, namely, a relatively small grain size and satisfactory orientation of the crystals into the (100)-plane. Since the piezoelectric layer 70 is thus formed satisfactorily, the effect of minimizing the amount of warpage of the passage-forming substrate 10 after formation of the piezoelectric elements 300 is obtained.

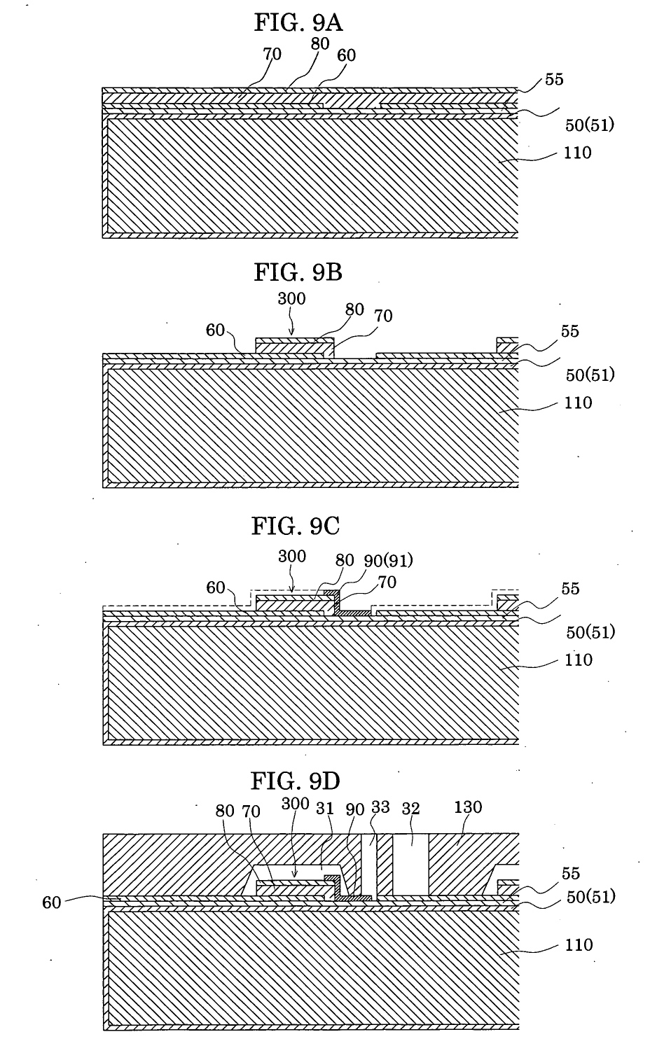

After the piezoelectric layer 70 is formed in the above-described manner, the upper electrode film 80 comprising, for example, iridium is formed on the entire surface of the passage-forming substrate wafer 110, as shown in FIG. 9A. Subsequently, as shown in FIG. 9B, the piezoelectric layer 70 and the upper electrode film 80 are patterned in regions opposed to the respective pressure generating chambers 12 to form the piezoelectric elements 300.

Next, the lead electrode 90 is formed. Specifically, a shown in FIG. 9C, a metal layer 91 comprising, for example, gold (Au) is formed on the entire surface of the passage-forming substrate wafer 110. Then, the metal layer 91 is patterned via a mask pattern (not shown), which comprises, for example, a resist, for each of the piezoelectric elements 300 to form the lead electrode 90.

Then, as shown in FIG. 9D, a protective plate wafer 130, which is a silicon wafer and will serve as a plurality of the protective plates 30, is bonded onto a side of the passage-forming substrate wafer 110 where the piezoelectric elements 300 are located. The protective plate wafer 130 has a thickness, for example, of the order of 400 μm. Thus, the rigidity of the passage-forming substrate wafer 110 is markedly increased by bonding the protective plate wafer 130 thereto.

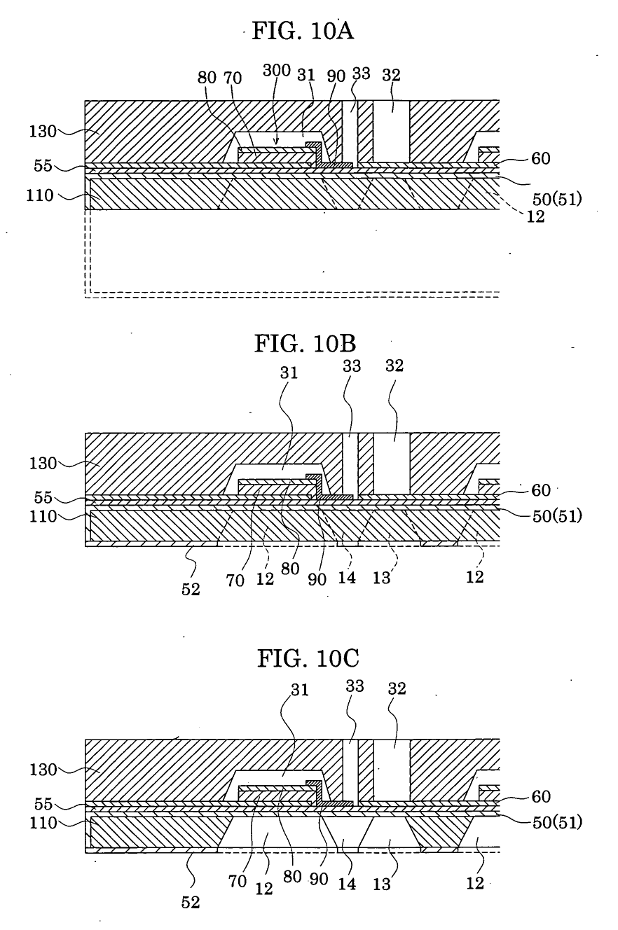

Then, as shown in FIG. 10A, the passage-forming substrate wafer 110 is polished to a certain thickness, and then is wet-etched with fluoronitric acid or the like to bring the passage-forming substrate wafer 110 into a predetermined thickness. In the present embodiment, for example, the passage-forming substrate wafer 110 is processed by etching to have a thickness of about 70 μm. Next, as shown in FIG. 10B, a mask film 52 comprising, for example, silicon nitride (SiN) is formed anew on the passage-forming substrate wafer 110, and is patterned into a predetermined shape. Then, the passage-forming substrate wafer 110 is subjected to anisotropic etching via the mask film 52 to form the pressure generating chambers 12, the communicating portion 13 and the ink supply paths 14 in the passage-forming substrate wafer 110, as shown in FIG. 10C.

Next, unnecessary regions of the outer peripheral edge portions of the passage-forming substrate wafer 110 and the protective plate wafer 130 are removed, for example, by cutting by means of dicing. Then, the nozzle plate 20 having the nozzle orifices 21 bored therein is bonded to the surface of the passage-forming substrate wafer 110 opposite to the protective plate wafer 130, and the compliance plate 40 is bonded to the protective plate wafer 130. The passage-forming substrate wafer 110 including the other members is divided into the passage-forming substrate 10, etc. of one-chip size as shown in FIG. 5 to produce the ink-jet recording head of the present embodiment.

As described above, when the ink-jet recording head is to be produced, namely, when the lower electrode film is to be formed, the sputtering target comprising platinum according to the present invention is used. By so doing, the resistance value of the lower electrode film becomes stable, and the values of Young's modulus and stress can be stabilized. Thus, an ink-jet recording head having stable ink ejection characteristics can be obtained. Furthermore, a highly reliable ink-jet recording head improved in adhesion between the lower electrode film and zirconium oxide can be obtained.

Although the present invention has been described based on the above embodiments, the present invention is not limited to these embodiments. For example, in the above-described embodiments, an explanation is offered for an example in which the lower electrode film of the piezoelectric element is formed with the use of the sputtering target of the present invention. Needless to say, however, the sputtering target of the present invention can be applied to the formation of all thin films. In the above embodiments, moreover, the sputtering apparatus of the magnetron type is illustrated. However, it goes without saying that other types of sputtering apparatuses can be adopted. It should be understood that such changes, substitutions and alterations can be made therein without departing from the spirit and scope of the invention as defined by the appended claims.

What is claimed is:

1. A sputtering target obtained by rolling a metallic material comprising platinum to form a metal plate having a predetermined thickness, and heating the metal plate for recrystallization,
said sputtering target having crystallographic textures isotropic in any of a planar direction and a thickness direction thereof, and a maximum value of Vickers hardness of 60 or lower.

2. The sputtering target according to claim 1, wherein a minimum value of the Vickers hardness is 50 or higher.

3. The sputtering target according to claim 1, wherein textures formed by rolling do not remain.

4. A sputtering apparatus comprising a cathode having the sputtering target of claim 1 fixed thereto, and a holding means for holding a substrate disposed in opposed relationship with the sputtering target.

5. The sputtering apparatus according to claim 4, wherein the sputtering target is disposed at a position eccentric with respect to a center of the substrate held by the holding means.

6. A liquid-jet head comprising a piezoelectric element having a lower electrode comprising a platinum film formed by the sputtering target of claim 1.

7. A liquid-jet head comprising a piezoelectric element having a lower electrode comprising a platinum film formed by the sputtering apparatus of claim 4.

8. A method for producing a sputtering target, comprising:
a rolling step of rolling a metallic material comprising platinum to form a metal plate having a predetermined thickness; and
a reheating step of heating the metal plate for recrystallization so that crystallographic textures constituting the metal plate are isotropic in any of a planar direction and a thickness direction of the metal plate, and a maximum value of Vickers hardness of the metal plate is 60 or lower.

9. The method for producing a sputtering target according to claim 8, wherein a heating temperature of the metal plate in the reheating step is 800° C. or higher.
